(19) United States
(12) Patent Application Publication
(10) Pub. No.: US 2017/0081176 A1
(43) Pub. Date: Mar. 23, 2017

(54) MEMS DEVICE, SEMICONDUCTOR DEVICE AND METHOD FOR MANUFACTURING THE SAME

(71) Applicants: HANGZHOU SILAN MICROELECTRONICS CO., LTD., Hangzhou (CN); HANGZHOU SILAN INTEGRATED CIRCUIT CO., LTD, Hangzhou (Xiasha) (CN)

(72) Inventors: Feng JI, Hangzhou (CN); Yongxiang WEN, Hangzhou (CN); Chen LIU, Hangzhou (CN); Hao ZHOU, Hangzhou (CN)

(73) Assignees: HANGZHOU SILAN MICROELECTRONICS CO., LTD., Hangzhou (CN); HANGZHOU SILAN INTEGRATED CIRCUIT CO., LTD, Hangzhou (Xiasha) (CN)

(21) Appl. No.: 14/981,461

(22) Filed: Dec. 28, 2015

(30) Foreign Application Priority Data
Sep. 22, 2015 (CN) 201510608392.4

(51) Int. Cl. B81B 7/00; H01L 23/26; B81C 1/00

(52) U.S. Cl. CPC B81B 7/0038; B81C 1/00285; H01L 23/26; B81B 2203/033; B81B 2203/0315; B81C 2203/0109; B81C 2201/0154; B81C 2201/0132; B81C 2201/0133; B81C 2201/0198

(57) ABSTRACT

The invention provides a MEMS device, semiconductor device, and method for manufacturing the same. The MEMS device comprises an enclosed cavity, the cavity having an inner wall extending in a first plane, the inner wall including a film deposition region for depositing a getter film, wherein one or more grooves are formed in the film deposition region, the angle between the sidewalls of the grooves and the first plane is more than 0° and less than 180°, and the getter film overlays the sidewall of the grooves. The invention can form the getter film in a smaller incident flux angle with a common sputtering, evaporation apparatus, that is, form the porous, high roughness getter.

### TECHNICAL FIELD

The present invention relates to manufacturing technology for getter film, and particularly to MEMS device, semiconductor device and method for manufacturing the same.

### BACKGROUND

Referring to FIG. 1, FIG. 1 illustrates a section structure of a typical MEMS device, mainly comprising a device substrate 101 and a capping substrate 102 which are bonded together by bonding material 105. An enclosed cavity 103 is formed by the bonded device substrate 101 and the capping substrate 102. It is generally required that a high vacuum level is maintained in the cavity 103, for example, the vacuum level should be in the order of mTorr.

The hermetic packaging is one of the challenges of MEMS technology. As to MEMS device, the hermetic sealing is important which even determines whether the device can work. Due to the residual gas present in and released by the surrounding materials of bonding material 105 and cavity 103, as the device working time goes on, the vacuum level in the cavity 103 may reduce gradually, thereby reducing the life time of the device. Therefore, in the prior art, a getter film 104 is typically used to absorb the residual gas after MEMS device packaging, to increase and maintain the vacuum level within the device. The getter film 104 may absorb the gas in the cavity 103 by physical adsorption and chemical reaction, etc, to extend the life time of the device and ensure the working stability and reliability of the device. The getter film 104 is usually a porous, high roughness film which has a nano columnar structure with high porosity, and its surface area become larger, thereby improving the gas adsorption effect.

Non-evaporative getter has an extensive application in the field of MEMS. At present, the main materials of common non-evaporative getter are Ti, Zr, Tu, and the alloy of these elements, etc, where Ti, Zr in single element state may be used as getter material. The getter, such as Ti, Zr, etc, may increase the vacuum level within MEMS device in a short time to reach normal working range, and can absorb the internal residual gas released by the packaged MEMS device at high temperature, thereby improving and maintaining the vacuum level of cavity in MEMS device. In general, the getter form of porous, high roughness may improve greatly the gas adsorption rate, gas adsorption quantity, and may still have a high gas adsorption rate under the normal temperature environment. Therefore, it has important significance for the development of MEMS device to develop the process technology of porous getter, particularly non-evaporative getter.

As mentioned above, the porous, high roughness getter has a larger surface area, and thus may improve greatly the gas adsorption performance of the getter. It is generally believed that, in order to form the porous, high roughness getter, the manufacturing process should meet the following three conditions: (1) lower substrate temperature; (2) lower deposition energy (for example, low power, high pressure, etc); (3) smaller incident flux angle. The lower substrate temperature, lower deposition energy, among others, may be readily achieved by adjusting the process parameters. But, the small incident flux angle is fixed at a desired angle by rotating the substrate.

In more particular, the smaller incident flux angle causes the sputtered atoms to produce self shielding effect, resulting in that the atoms arriving at substrate previously block the path of the subsequent atoms, reducing the opportunity of the atoms selecting deposition positions, so that the film thus formed is in the state of porous, high roughness. According to the document, when the deposition incident flux angle is 60°-90°, the surface area per unit mass of the getter film is 2 m²/g; and when the deposition incident flux angle is 10°-60°, the surface area per unit mass of the getter film will increase with the decrease of the deposition angle, and when the deposition incident flux angle is 10°, the surface area per unit mass of the getter film may be 26 m²/g.

According to above discussion, the incident flux angle is one of key factors in manufacturing process of the porous, high roughness getter film. At present, the incident flux angles as achieved by many facilities of semiconductor factories are 90 degree, and the substrate can not be deflected, thus these facilities do not have the ability to adjust the incident flux angle of sputtering, evaporation, causing the porous, high surface roughness getter can not be fabricated.

### SUMMARY

The technical problem to be solved by present invention is to provide a MEMS device, semiconductor device and method for manufacturing the same, which can form getter film in a smaller incident flux angle with common sputtering, evaporation apparatus, that is, forming porous, high roughness getter film.

In order to solve the technical problem described above, the present invention provides a MEMS device comprising an enclosed cavity, the cavity having an inner wall extending in a first plane, the inner wall including a film deposition region for depositing a getter film, wherein one or more grooves are formed in the film deposition region, the angle between the sidewalls of the grooves and the first plane is more than 0° and less than 180°, and the getter film overlays the sidewall of the grooves.

According to one embodiment of the present invention, the angle between the sidewalls of the grooves and the first plane is 20° ˜90°.

According to one embodiment of the present invention, the shape of the grooves is circular-arc, trapezoid, or V shape.

According to one embodiment of the present invention, the material of the getter film is selected from Ti, Zr, Tu, or the alloy formed by any combination of these elements.

According to one embodiment of the present invention, the adjacent grooves adjoin each other, or have a spacing therebetween.

According to one embodiment of the present invention, the MEMS device comprises a device substrate and a capping substrate, a first recess is formed on the device substrate, and a second recess is formed on the capping substrate, the device substrate and capping substrate are bonded, the first and second recesses joint together to form the cavity.

In order to solve the technical problem described above, the present invention provides a semiconductor device, comprising: a semiconductor substrate having a surface extending in a first plane, the surface including a film deposition region for depositing a getter film, wherein one or more grooves are formed in the film deposition region, the angle between the sidewalls of the grooves and the first plane is more than 0° and less than 180°, and the getter film overlays the sidewalls of the grooves.

According to one embodiment of the present invention, the angle between the sidewalls of the grooves and the first plane is 20° ˜90°.

According to one embodiment of the present invention, the shape of the grooves is circular-arc, trapezoid, or V shape.

According to one embodiment of the present invention, the material of the getter film is selected from Ti, Zr, Tu, or the alloy formed by any combination of these elements.

According to one embodiment of the present invention, the adjacent grooves adjoin each other, or have a spacing there between.

In order to solve the technical problem described above, the present invention provides a method for manufacturing a MEMS device, comprising:

providing a device substrate and a capping substrate, a first recess being formed on the device substrate, and a second recess being formed on the capping substrate, the first recess or the second recess having an inner wall extending in a first plane, the inner wall including a film deposition region for depositing a getter film;

forming one or more grooves on the film deposition region, the angle between the sidewalls of the grooves and the first plane being more than 0° and less than 180°;

depositing the getter film on the film deposition region to overlay the sidewalls of the grooves;

bonding the device substrate and the capping substrate, the first and second recesses jointing together to form an enclosed cavity.

According to one embodiment of the present invention, when depositing the getter film, an incident flux direction is perpendicular to the first plane.

According to one embodiment of the present invention, the angle between the sidewalls of the grooves and the first plane is 20° ˜90°.

According to one embodiment of the present invention, the shape of the grooves is circular-arc, trapezoid, or V shape.

According to one embodiment of the present invention, the material of the getter film is selected from Ti, Zr, Tu, or the alloy formed by any combination of these elements.

According to one embodiment of the present invention, the adjacent grooves adjoin each other, or have a spacing there between.

According to one embodiment of the present invention, forming the one or more grooves on the film deposition region comprises:

forming a mask layer at least on the film deposition region, patterning the mask layer to define a pattern of the grooves;

etching the film deposition region with the mask layer as a mask, to form the grooves;

removing the patterned mask layer.

According to one embodiment of the present invention, the getter film is formed by sputtering, evaporation.

In order to solve the technical problem described above, the present invention provides a method for manufacturing a semiconductor device, comprising:

providing a semiconductor substrate having a surface extending in a first plane, the surface including a film deposition region for depositing a getter film;

forming one or more grooves on the film deposition region, the angle between the sidewalls of the grooves and the first plane being more than 0° and less than 180°;

depositing the getter film on the film deposition region to overlay the sidewalls of the grooves;

According to one embodiment of the present invention, when depositing the getter film, an incident flux direction is perpendicular to the first plane.

According to one embodiment of the present invention, the angle between the sidewalls of the grooves and the first plane is 20° ˜90°.

According to one embodiment of the present invention, the shape of the grooves is circular-arc, trapezoid, or V shape.

According to one embodiment of the present invention, the material of the getter film is selected from Ti, Zr, Tu, or the alloy formed by any combination of these elements.

According to one embodiment of the present invention, the adjacent grooves adjoin each other, or have a spacing there between.

According to one embodiment of the present invention, forming the one or more grooves on the film deposition region comprises:

forming a mask layer at least on the film deposition region, patterning the mask layer to define a pattern of the grooves;

etching the film deposition region with the mask layer as a mask, to form the grooves;

removing the patterned mask layer.

According to one embodiment of the present invention, the getter film is formed by sputtering, evaporation.

Compared with the prior, the invention has the following advantages:

In the MEMS device of the embodiments of present invention, one or more grooves are formed in the film deposition region in the inner wall of the cavity, the angle between the sidewalls of the grooves and the inner wall of the cavity is more than 0° and less than 180°, the incident flux direction during the getter film deposition is substantially perpendicular to the first plane, which makes the sidewalls of the grooves and incident flux direction form a small angle, so that the porous, high roughness getter film can be formed by common sputtering, evaporation film deposition apparatus without deflecting the substrate, it may facilitate to increase the effective surface area of the getter film.

The method for manufacturing MEMS device is compatible with wafer level packaging process, and has a wide application prospect in wafer level hermetic packaging technology.

### BRIEF DESCRIPTION OF THE DRAWINGS

FIG. 1 is a schematic diagram of section structure of a MEMS device in prior art;

FIG. 2 is a schematic diagram of section structure of a MEMS device according to the first embodiment of the invention;

FIG. 3 is a schematic diagram of section structure of a semiconductor device according to the second embodiment of the invention;

FIG. 4 is a schematic diagram of section structure of a semiconductor device according to the third embodiment of the invention;

FIGS. 5-9 are schematic diagrams of respective section structure corresponding to each step in a manufacturing method of semiconductor device according to the fourth embodiment of the invention;

FIGS. 10-12 are schematic diagrams of respective section structure corresponding to each step in a manufacturing method of semiconductor device according to the fifth embodiment of the invention;

FIG. 13 is a schematic diagram of section structure of a MEMS device formed by a manufacturing method of MEMS device according to the sixth embodiment of the invention;

FIG. 14 is a partial scanning electron microscopy diagram of a semiconductor device according to the second embodiment of the invention;

FIG. 15 is a partial enlarged drawing of FIG. 14;

FIG. 16 is a surface scanning electron microscopy diagram of a getter film on side walls of grooves in a semiconductor device according to the second embodiment of the invention;

FIG. 17 is a surface scanning electron microscopy diagram of a getter film on semiconductor substrate in a semiconductor device according to the second embodiment of the invention;

FIG. 18 is a top view of scanning electron microscopy of a getter film on side walls of grooves and on a semiconductor substrate in a semiconductor device according to the second embodiment of the invention;

FIG. 19 is a partial enlarged drawing of FIG. 18;

FIG. 20 is a scanning electron microscopy diagram of cross section of a getter film on a semiconductor substrate in a semiconductor device according to the second embodiment of the invention;

FIG. 21 is a surface scanning electron microscopy diagram of a getter film on a semiconductor substrate in a semiconductor device according to the second embodiment of the invention.

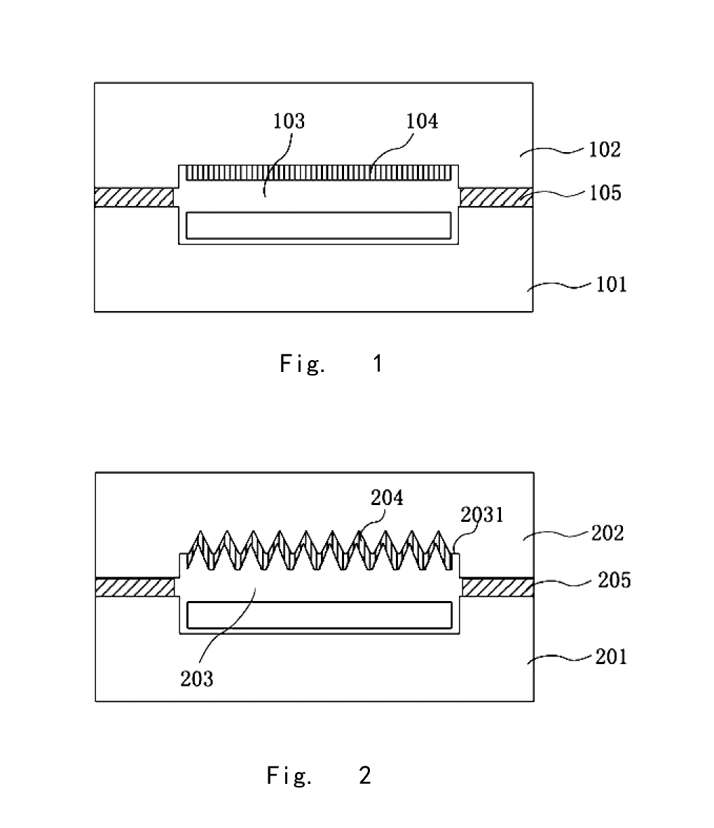

### DETAILED DESCRIPTION

The invention will be further described in connection with the particular embodiments and drawings, but the scope of the invention should not be limited in any manner.

### First Embodiment

Referring to FIG. 2, a MEMS device of the first embodiment has an enclosed cavity 203. The cavity 203 is formed by bonding a device substrate 201 and a capping substrate 202. In more particular, the device substrate 201 and capping substrate 202 each have a recess, the device substrate 201 and capping substrate 202 may be bonded together by bonding material 205, so that the recesses on the device substrate 201 and capping substrate 202 align and joint together to form the cavity 203. The device substrate 201 and capping substrate 202 may be silicon substrates, such as silicon substrates in <100> crystal orientation, <111> crystal orientation, or <110> crystal orientation. A variety of MEMS devices may be formed in the recess on the device substrate 201.

Preferably, a overflow groove may be formed on the device substrate 201 and/or capping substrate 202 between bonding material 205 and cavity 203, for accommodating the bonding material 205 extending laterally during bonding, to avoid the bonding material 205 flowing into the cavity 203.

The cavity 203 has a inner wall 2031. For example, the inner wall 2031 may be the bottom surface of the recess on the capping substrate 202, and extend in the first plane. In general, the first plane may be parallel to the surface where the recess on the capping substrate 202 is present.

The inner wall 2031 comprises a film deposition region, to deposit getter film 204. One or more grooves are formed on the inner wall of the film deposition region, the angle between the sidewalls of the grooves and the first plane is more than 0° and less than 180°, and the getter film 204 overlays the sidewalls of the grooves. Preferably, the angle between the sidewalls of the grooves and the first plane is 20° ˜90°.

The shape of the grooves may be circular-arc, trapezoid, or V shape, for example, the V shape as an example shown in FIG. 2. In the first embodiment, the adjacent grooves adjoin each other. In other words, there is substantially no spacing or gap between the adjacent grooves.

The getter film 204 may be any proper type of getter, for example, non-evaporative getter. The material of getter film 204 may be selected from Ti, Zr, Tu, or the alloy formed by any combination of these elements. In addition, the getter film 204 may also contain light absorption material, such as Ni, etc.

### Second Embodiment

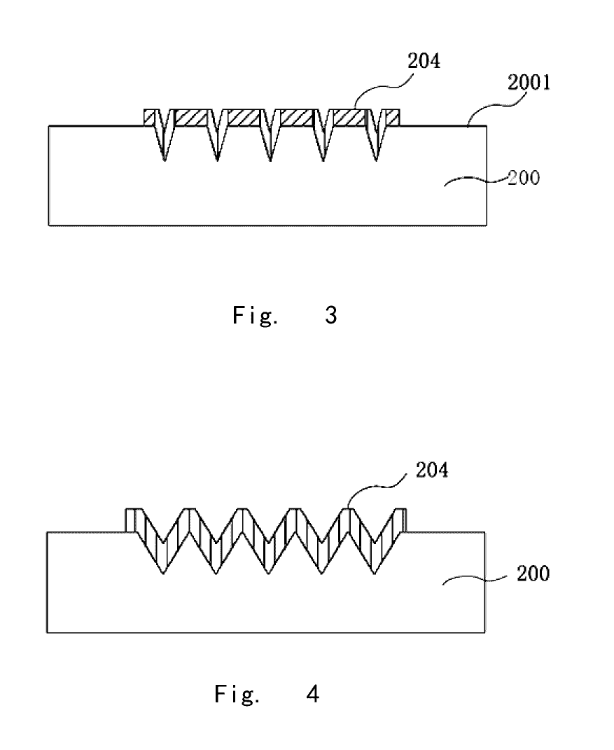

Referring to FIG. 3, the semiconductor device of the second embodiment comprises: a semiconductor substrate 200 having a surface 2001 extending in a first plane, and the surface 2001 comprises a film deposition region to deposit getter film. The semiconductor substrate 200 may be a common wafer scale packaging substrate, such as heat resistant glass, silicon substrate, etc. As a non-limiting example, the semiconductor substrate 200 in this embodiment is silicon substrate, such as silicon substrates in <100> crystal orientation, <111> crystal orientation, or <110> crystal orientation.

One or more grooves are formed on the film deposition region, the angle between the sidewalls of the grooves and the first plane is more than 0° and less than 180°, and the getter film 204 overlays the sidewalls of the grooves. Preferably, the angle between the sidewalls of the grooves and the first plane is 20° ˜90°.

The shape of the grooves may be circular-arc, trapezoid, or V shape, for example, the V shape as an example shown in FIG. 3. In the second embodiment, there is a spacing between the adjacent grooves. In other words, the adjacent grooves are spaced by the surface 2001 of semiconductor substrate 200. The getter film 204 overlays the surface 2001 between grooves.

The getter film 204 may be any proper type of getter, for example, non-evaporative getter. The material of getter film 204 may be selected from Ti, Zr, Tu, or the alloy formed by any combination of these elements.

The semiconductor device in the second embodiment may be a portion of MEMS device, or may be a portion of other type of semiconductor device.

### Third Embodiment

Referring to FIG. 4, FIG. 4 illustrates a section structure view of a semiconductor device according to the third embodiment, and is substantially similar to FIG. 3, except that: the adjacent grooves adjoin each other and have no spacing therebetween. In addition, the angle between the sidewalls of the grooves and the first plane is slightly different.

### Fourth Embodiment

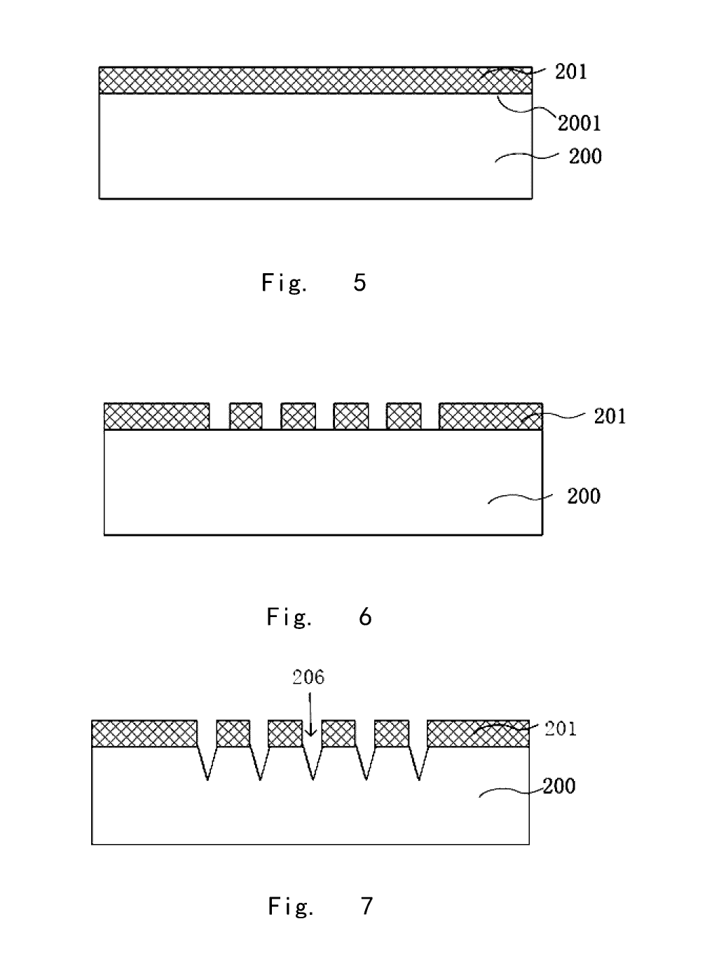

The manufacturing method of semiconductor device according to the fourth embodiment is described in detail in combination with FIGS. 5-9 in the following. The manufacturing method according to the fourth embodiment relates to the semiconductor device of the second embodiment.

Referring to FIG. 5, the semiconductor substrate 200 is provided. The semiconductor substrate 200 may be silicon substrate, such as silicon substrates in <100> crystal orientation, <111> crystal orientation, or <110> crystal orientation. The semiconductor substrate 200 has a surface 2001 extending in a first plane.

A mask layer 201 is deposited on the surface 2001. The material of mask layer 201 may be photo resist, SiO₂, Si₃N₄, Au, Cu or other proper materials.

As a non-limiting example, the mask layer 201 may be SiO₂ layer having thickness of 1 KÅ-10 KÅ, and its forming method may be surface oxidation method.

Referring to FIG. 6, the mask layer 201 is patterned, to define the patterns of the grooves, forming etching windows. The method for patterning the mask layer 201 may comprise photolithography development, wet etching, dry etching, etc.

Referring to FIG. 7, with the patterned mask layer 201 as a mask, the semiconductor substrate 200 is etched to form one or more grooves 206. The etching method for grooves 206 may be one or more of dry etching, wet etching, ion beam bombarding etching, laser cutting, ion milling, etc. As a non-limiting example, a wet etching is performed using corrosive liquid such as KOH or TMAH to form grooves 206. Preferably, the angle between the sidewalls of the grooves 206 and the first plane may be 54.7°, the shape of the grooves 206 is V-shape, and the depth of the grooves 206 is 5-30 μm.

In the plurality of grooves 206 thus formed, there is a spacing between the adjacent grooves 206. In other words, the adjacent grooves 206 are spaced by the surface of the semiconductor substrate 200.

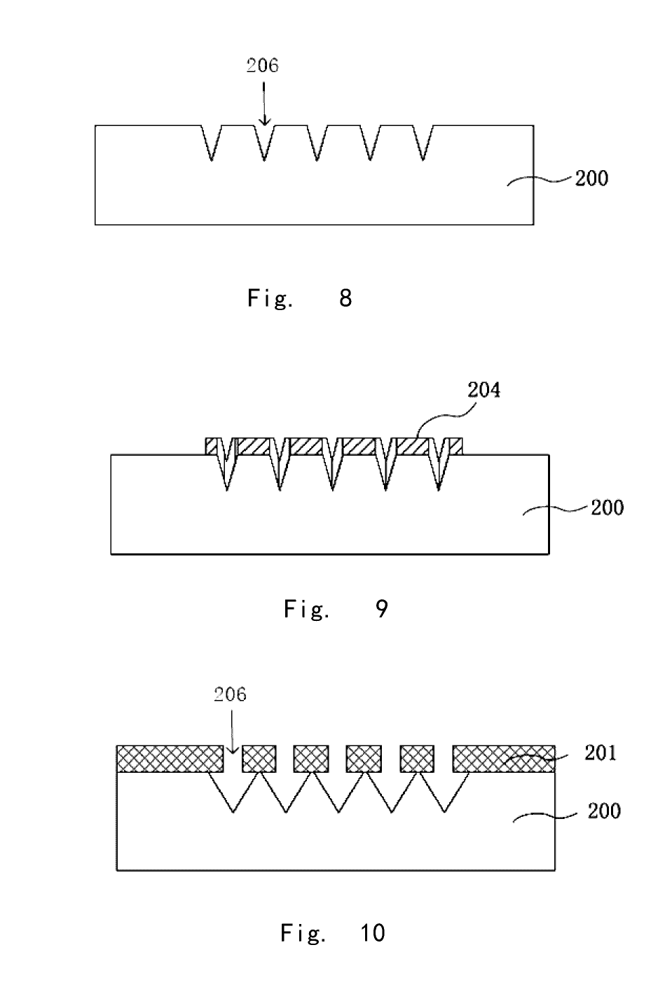

Referring to FIG. 8, the patterned mask layer is removed. For example, the mask layer of SiO₂ material may be removed by using BOE corrosive liquid.

Referring to FIG. 9, the getter film 204 is deposited, and overlays at least sidewalls of the grooves. In present embodiment, the getter film 204 also overlays the surface of semiconductor substrate 200 between the adjacent grooves.

The forming method of getter film 204 may be sputtering, evaporation, etc, and the atom incident flux direction is perpendicular to the first plane. Since the angle between the sidewalls of the grooves and the first plane is more than 0° and less than 180°, the angle between the incident flux direction and the sidewalls of the grooves must be less than 90°. Therefore, by controlling the tilt of the sidewalls of grooves, a preferred angle between the incident flux direction and the sidewalls of grooves may be formed, thereby forming the porous, high surface roughness getter film 204.

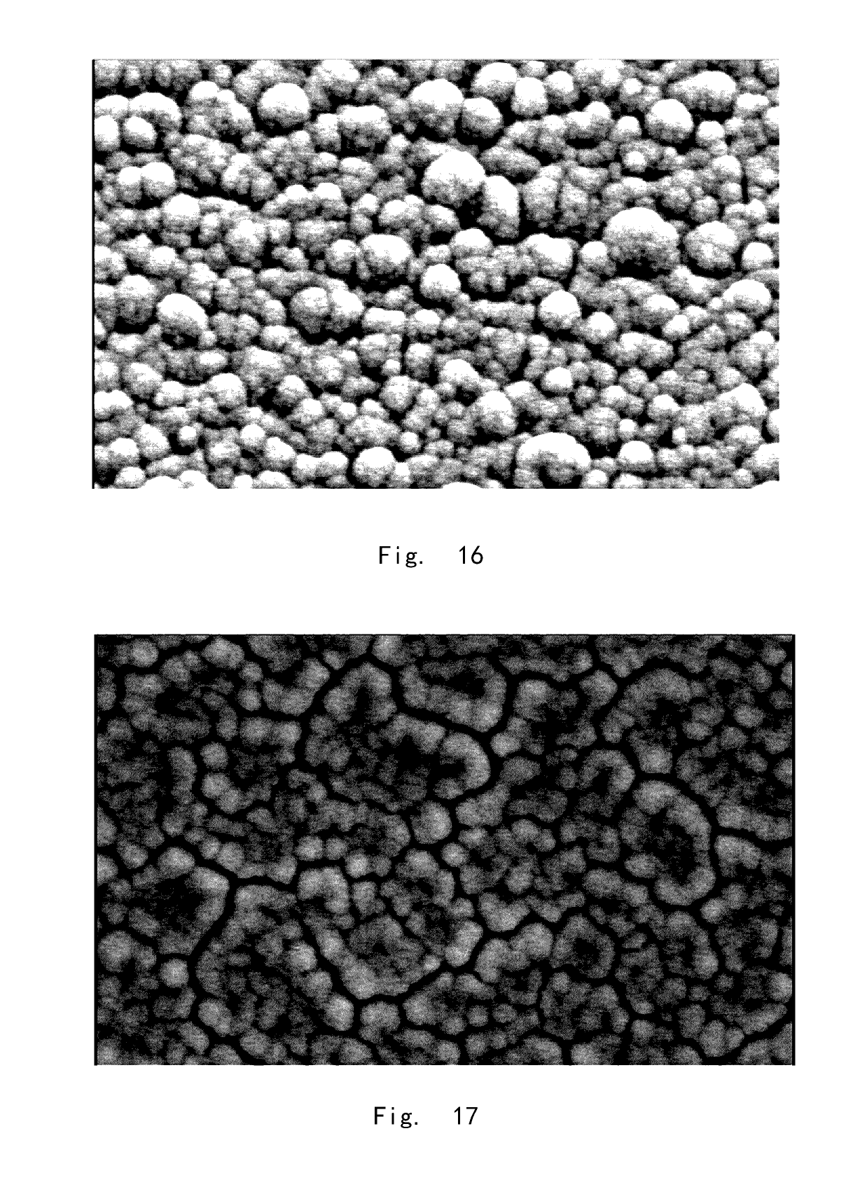

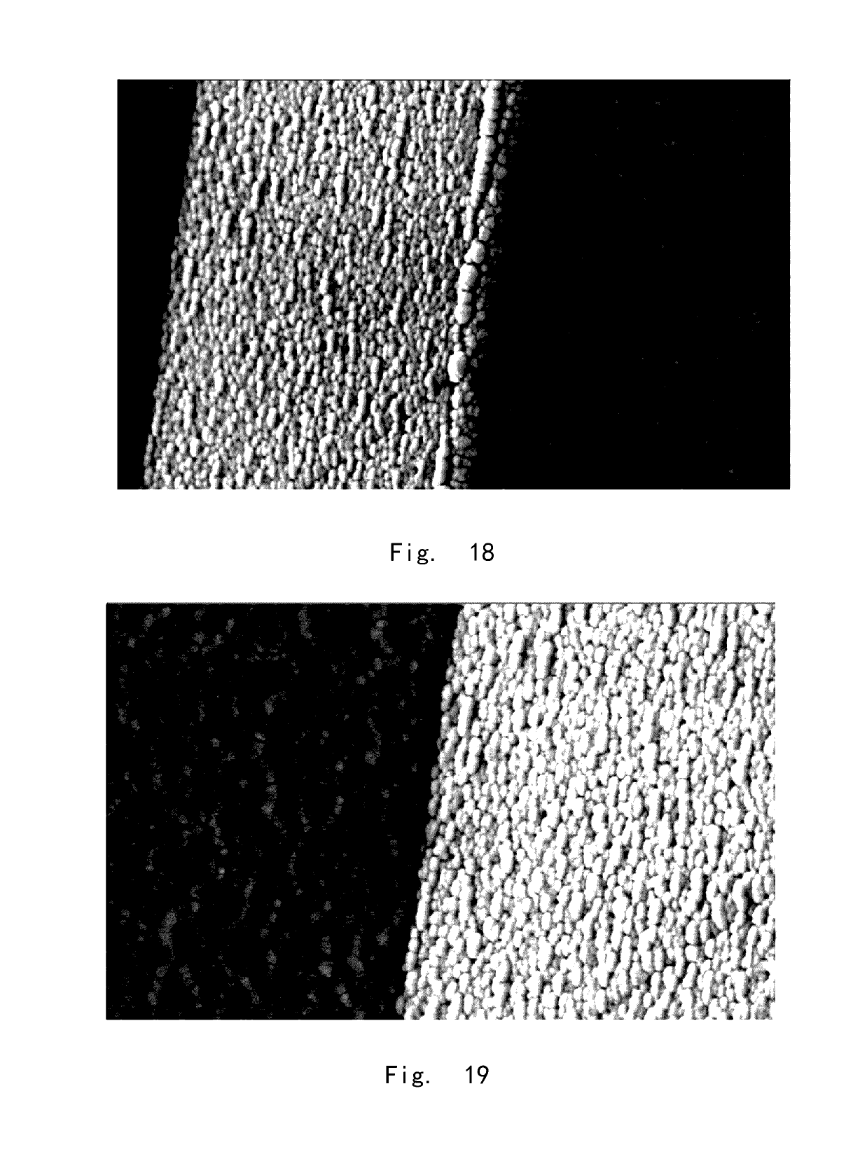

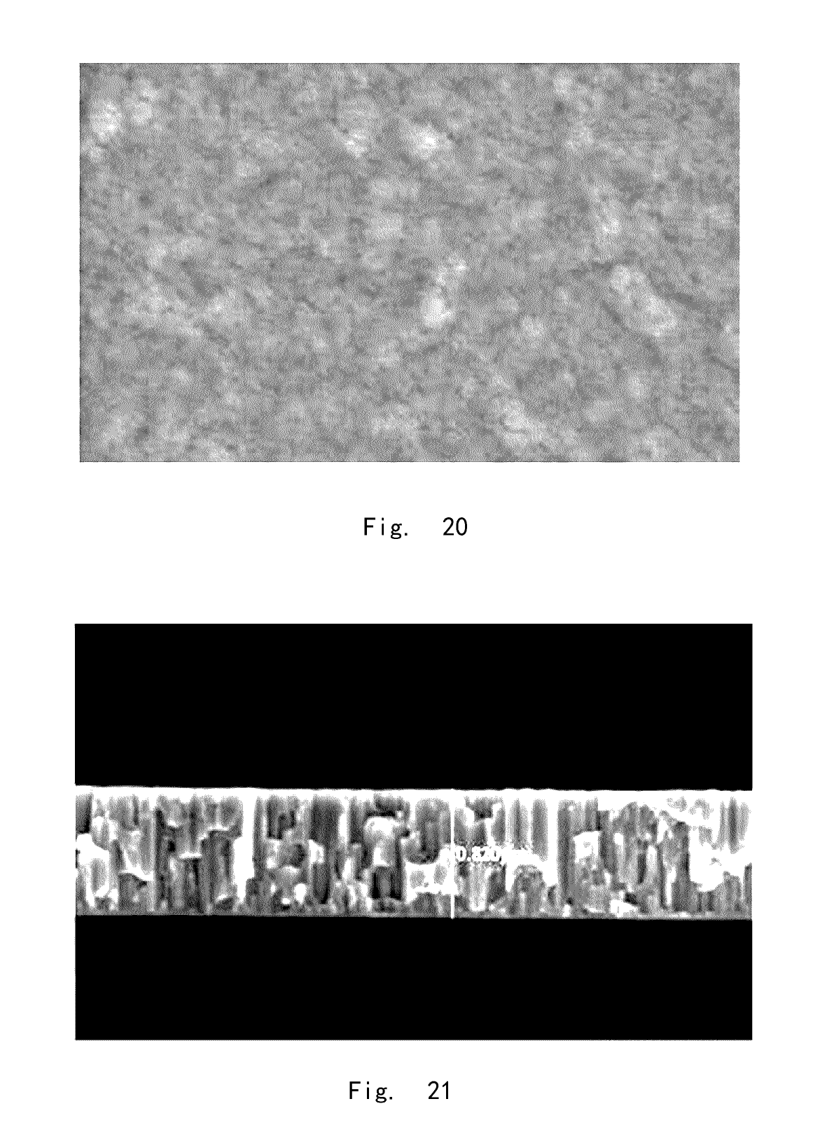

It should be noted that the surface of semiconductor substrate 200 between the adjacent grooves is still perpendicular to the incident flux direction. Thus, the getter film 204 overlaid on the surface of semiconductor substrate 200 between the adjacent grooves is denser, and its porosity and surface roughness are lower. It can be seen from FIGS. 14-21, which show scanning electron microscopy diagrams captured at different viewing angles and positions. In particular, FIG. 14 is a scanning electron microscopy diagram of juncture of the getter film 204 on semiconductor substrate 200 and the getter film 204 on the sidewalls of grooves in FIG. 3 or FIG. 9; FIG. 15 is a partial enlarged drawing of FIG. 14 to show morphology at juncture of the getter film 204 more clearly; FIG. 16 is a surface scanning electron microscopy diagram of the getter film on the sidewalls of grooves in FIG. 14; FIG. 17 is a surface scanning electron microscopy diagram of the getter film on semiconductor substrate in FIG. 14; FIG. 18 is a top view of scanning electron microscopy of the juncture corresponding to FIG. 14; FIG. 19 is a partial enlarged drawing of FIG. 18; FIG. 20 is a scanning electron microscopy diagram of the cross section of the getter film on semiconductor substrate in FIG. 14; FIG. 21 is a surface scanning electron microscopy diagram of the getter film on the sidewalls of grooves in FIG. 14.

In particular, it can be seen from the comparison of FIG. 16 with FIG. 17 that the getter film on the sidewalls of grooves shown in FIG. 16 has higher porosity and higher surface roughness, in other words, the getter film on the sidewalls of grooves has a good nano columnar structure, which makes the getter film have high gas adsorption effect; whereas the getter film on semiconductor substrate shown in FIGS. 17, 20, and 21 is denser, its porosity is poor and surface roughness is lower, not having nano columnar structure. In addition, it can be seen clearly from the top views of FIGS. 18, 19 the comparison of the getter film on the sidewalls of grooves with the getter film on semiconductor substrate.

In practice, in the prior art, if the deposition device does not have the function of deflecting the angle of the substrate, the getter film will be deposited on the surface of the substrate at the incident flux angle of substantially 90°, so that the entire getter film will be a dense structure as shown in FIGS. 17, 20, 21, causing the gas adsorption effect poor. In present embodiment, the getter film on the sidewalls of grooves has high porosity, high roughness, and improves at least the gas adsorption effect of the getter film. Further more, if there is no spacing between the adjacent grooves, substantially the whole getter film is on the sidewalls of grooves, as shown in FIGS. 2 and 4, which will further improve the gas adsorption effect.

Of cause, when forming the getter film, the incident flux direction may not be perpendicular to the first plane, so that the angel between the incident flux direction and the first plane is an other angle than 90°. For example, in the deposition apparatus having the function of deflecting the substrate, the angle between the incident flux direction and the sidewalls of the grooves can be optimized by inclination angle of the sidewalls of the grooves with respect to the first plane in combination with the substrate deflection, thereby forming getter film with high gas adsorption.

### Fifth Embodiment

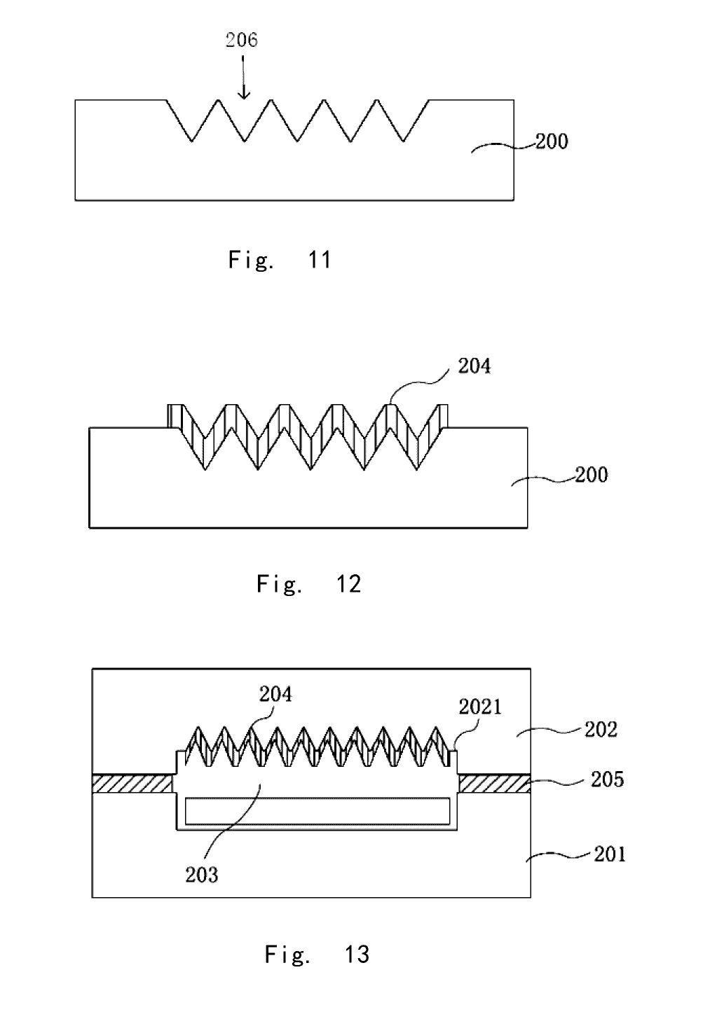

The manufacturing method of semiconductor device according to the fifth embodiment is described in detail in combination with FIGS. 10-12 in the following. The manufacturing method according to the fifth embodiment relates to the semiconductor device of the third embodiment.

In particular, in the manufacturing method of the fifth embodiment, the previous steps may refer to FIGS. 5-7 and relevant description; and the subsequent steps may be described referring to FIGS. 10-12.

Referring to FIG. 10, after a certain time period for wet etching with the patterned mask layer 201, the etch time continues to increase, causing the grooves wider and deeper, so that the adjacent grooves 206 adjoin each other.

Referring to FIG. 11, the patterned mask layer 201 is removed, with reference to the previous description for the removing method.

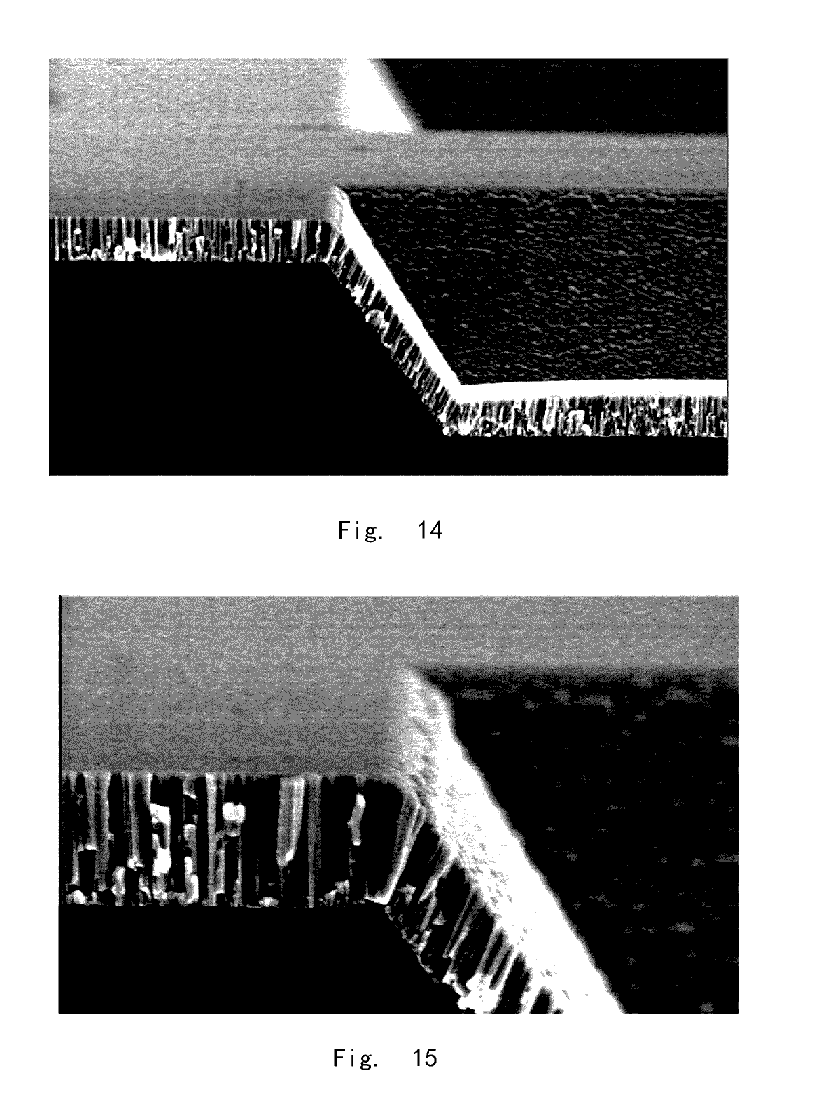

Referring to FIG. 12, the getter film 204 is deposited, and overlays the sidewalls of the grooves. Reference may be made to the previous description for the forming method of getter film.

### Six Embodiment

Referring to FIG. 13, the device substrate 201 and capping substrate 202 are provided. A first recess is formed on the device substrate 201, and a second recess is formed on the capping substrate 202. The first recess or the second recess has an inner wall 2021 extending in a first plane, as a non-limiting example, the inner wall 2021 is in the second recess within the capping substrate 202, and in particular, the inner wall 2021 is at the bottom surface of the second recess. Of cause, the inner wall 2021 may also be in the first recess of the device substrate 201.

Thereafter, one or more grooves are formed on the inner wall 2021, the angle between the sidewalls of the grooves and the first plane is more than 0° and less than 180°. Reference may be made to the concerned description of the fourth and fifth embodiments for the forming method of the grooves.

Thereafter, a getter film 204 is deposited, and overlays at least the sidewalls of the grooves, and the incident flux direction during deposition is perpendicular to the first plane. It should be noted that the “perpendicular” described herein is not limited to strict vertical, but further comprises the conditions that have moderate error in perpendicular direction.

Reference may be made to the relevant description of the fourth and fifth embodiments for the forming method of the getter film.

Thereafter, the device substrate 201 and capping substrate 202 may be bonded, for example, by the bonding material 205. After bonding, the first and second recesses joint together to form an enclosed cavity 203.

It will be appreciated that the embodiments set forth above are intended to be illustrative, not limiting of the invention, but any invention without going beyond the ambit of the present invention, including but not limited to the modifications to local configuration, replacement for the device type or version, and other non substantial modifications or replacements should be considered to fall within the scope of the present invention.

What is claimed is:

1. A MEMS device, comprising an enclosed cavity, the cavity having an inner wall extending in a first plane, the inner wall including a film deposition region for depositing getter film, wherein one or more grooves are formed in the film deposition region, the angle between the sidewalls of the grooves and the first plane is more than 0° and less than 180°, and the getter film overlays the sidewalls of the grooves.

2. The MEMS device according to claim 1, wherein the angle between the sidewalls of the grooves and the first plane is 20°˜90°.

3. The MEMS device according to claim 1, wherein the shape of the grooves is circular-arc, trapezoid, or V shape.

4. The MEMS device according to claim 1, wherein the material of the getter film is selected from Ti, Zr, Tu, or the alloy formed by any combination of these elements.

5. The MEMS device according to claim 1, wherein the adjacent grooves adjoin each other, or have a spacing therebetween.

6. The MEMS device according to claim 1, wherein the MEMS device comprises a device substrate and a capping substrate, a first recess is formed on the device substrate, and a second recess is formed on the capping substrate, the device substrate and capping substrate are bonded, the first and second recesses joint together to form the cavity.

7. A semiconductor device, comprising: a semiconductor substrate having a surface extending in a first plane, the surface including a film deposition region for depositing a getter film, wherein one or more grooves are formed in the film deposition region, the angle between the sidewalls of the grooves and the first plane is more than 0° and less than 180°, and the getter film overlays the sidewalls of the grooves.

8. The semiconductor device according to claim 7, wherein the angle between the sidewalls of the grooves and the first plane is 20°˜90°.

9. The semiconductor device according to claim 7, wherein the shape of the grooves is circular-arc, trapezoid, or V shape.

10. The semiconductor device according to claim 7, wherein the material of the getter film is selected from Ti, Zr, Tu, or the alloy formed by any combination of these elements.

11. The semiconductor device according to claim 7, wherein the adjacent grooves adjoin each other, or have a spacing therebetween.

12. A method for manufacturing a MEMS device, comprising:
providing a device substrate and a capping substrate, a first recess being formed on the device substrate, and a second recess being formed on the capping substrate, the first recess or the second recess having an inner wall extending in a first plane, the inner wall including a film deposition region for depositing a getter film;
forming one or more grooves on the film deposition region, the angle between the sidewalls of the grooves and the first plane being more than 0° and less than 180°;
depositing the getter film on the film deposition region to overlay the sidewalls of the grooves;
bonding the device substrate and the capping substrate, the first and second recesses jointing together to form an enclosed cavity.

13. The method according to claim 12, wherein when depositing the getter film, an incident flux direction is perpendicular to the first plane.

14. The method according to claim 12, wherein the angle between the sidewalls of the grooves and the first plane is 20°˜90°.

15. The method according to claim 12, wherein the shape of the grooves is circular-arc, trapezoid, or V shape.

16. The method according to claim 12, wherein the material of the getter film is selected from Ti, Zr, Tu, or the alloy formed by any combination of these elements.

17. The method according to claim 12, wherein the adjacent grooves adjoin each other, or have a spacing therebetween.

18. The method according to claim 12, wherein forming the one or more grooves on the film deposition region comprises:
forming a mask layer at least on the film deposition region, patterning the mask layer to define a pattern of the grooves;
etching the film deposition region with the patterned mask layer as a mask, to form the grooves;
removing the patterned mask layer.

19. The method according to claim 12, wherein the getter film is formed by sputtering, evaporation.

20. A method for manufacturing a MEMS device, comprising:
providing a semiconductor substrate having a surface extending in a first plane, the surface including a film deposition region for depositing a getter film;
forming one or more grooves on the film deposition region, the angle between the sidewalls of the grooves and the first plane being more than 0° and less than 180°;
depositing the getter film on the film deposition region to overlay the sidewalls of the grooves;

21. The method according to claim 20, wherein when depositing the getter film, an incident flux direction is perpendicular to the first plane.

22. The method according to claim 20, wherein the angle between the sidewalls of the grooves and the first plane is 20°˜90°.

23. The method according to claim 20, wherein the shape of the grooves is circular-arc, trapezoid, or V shape.

24. The method according to claim 20, wherein the material of the getter film is selected from Ti, Zr, Tu, or the alloy formed by any combination of these elements.

25. The method according to claim 20, wherein the adjacent grooves adjoin each other, or have a spacing therebetween.

26. The method according to claim 20, wherein forming the one or more grooves on the film deposition region comprises:
forming a mask layer at least on the film deposition region, patterning the mask layer to define a pattern of the grooves;
etching the film deposition region with the mask layer as a mask, to form the grooves;
removing the patterned mask layer.

27. The method according to claim 20, wherein the getter film is formed by sputtering, evaporation.
